(19) United States
(12) Patent Application Publication
(10) Pub. No.: US 2004/0015771 A1
(43) Pub. Date: Jan. 22, 2004

(54) Error correction for non-volatile memory

(76) Inventors: Menahem Lasser, Kohav-Yair (IL); Avraham Meir, Rishon-Lezion (IL)

Correspondence Address: William H. Dippert, Esq., Reed Smith LLP, 29th Floor, 599 Lexington Avenue, New York, NY, 10022-7650, US

(21) Appl. No.: 10/197,316

(22) Filed: Jul. 16, 2002

(51) Int. Cl. G11C 29/00

(52) U.S. Cl. 714/763

(57) ABSTRACT

A method of accessing control information of a non-volatile solid state memory storage, including reading said control information; reading error correction code data shared by said control information and by other associated data; analyzing said error correction code data to determine if said control information is erroneous; and if erroneous, correcting said control information based on said error correction code data.

### FIELD OF THE INVENTION

The present invention relates to error correction codes for non-volatile memory.

### BACKGROUND OF THE INVENTION

Non-volatile memory devices and especially solid state memory devices are not perfect and tend to wear out over time. One main effect of such wear is the creation of errors in stored data, typically, by reducing the reliability of read, write and/or storage mechanisms of particular bits or banks of bits. When referring to such errors, it is common to refer to orders of magnitude of errors, and any calculations made on such errors magnitudes are approximate. In a typical device, reliability is defined as an order of magnitude of errors which the device is expected to be better than, if it to be considered reliable. Different device types have different typical and industry accepted reliability, depending, for example on the technology used and the manufacturing process tolerance which can be achieved. High quality DRAM memories typically have a very low bit error rate. Bit error rates can get as high as the order of 1:10⁸ in a low quality solid state flash memory device. For this reason, solid state flash memory devices usually have error detection and error correction codes associated with each data sector. In a typical implementation, each 512 byte sector has 16 bytes of associated data, some of which associated data is used for storing error correction codes and some of which is used to store control information. When the data sector is read, the associated data is also read and the codes data are analyzed to determine if there is an error and/or to correct such an error, if possible.

In general, error detection codes that can reliably detect an error in no more than N bits (e.g., of order N), takes up less storage space than a code that can reliably correct such an error. That a code can sometimes, but not reliably, detect or correct an error of higher order will not increase the order of the code. In addition, some error detection codes can serve as error correction codes as well, in which case the detection order may be greater than the correction order.

Typically, each data sector has associated control information. Examples of such control information include, an indication if a data sector is empty or in use, an indication of data is valid or invalid (e.g., superseded by new data), an indication if a data sector is defective and/or a logical sector number as viewed by driver software. This control information may be stored, for example, in association with the data sector, for example in the above described associated data area. This control information is as prone to errors as the data sectors. In some implementations, the control area is duplicated. For a 100 bits control area, if duplicated, the probability of losing some control information in both copies is better than 1:10¹², assuming the above memory bit error rates However, if a very low quality memory is used, this method of duplication is not sufficient. For example, if the error rate is on the order of 1:10⁵, the duplication method will yield an error rate on the order of 1:10⁶ for both copies of the control area being in error. This is a generally unacceptable error rate and may be one of the reasons that very low quality memory components are not used.

Version 0.3 of the YAFFS specification (http://www.aleph1.co.uk/armlinux/projects/yaffs/yaffs.html) describes a flash file system in which tags are used for each block. 48 bits of error correction codes are used for each 512 bytes of data, with 24 bits used for each 256 bytes of data. The tags are also protected using an error correction code, in which a 12 bit error correction code is provided for 64 bits (inclusive of the 12 bits) of tags data

### SUMMARY OF THE INVENTION

An aspect of some embodiments of the invention relates to sharing one or more error correction codes between a data section and an associated control section in a solid state non-volatile memory. It is noted that using such a shared code may, in some cases, lengthen access time to control information (e.g., by requiring reading a data sector to access a control area and/or by requiring applying the code to more data). However, this potential drawback may be outweighed by the ability to use lower quality memory. In addition, the total number of bits required for a code that covers both the data and the control sections is typically smaller that the total number of bits required for separate codes for data and control areas. In an exemplary embodiment of the invention, the data section is 256 or 512 bytes long and the control section is 4 to 16 bytes long, including any error correction codes. However, the control and/or data sections may be shorter or longer, depending on the exact implementation.

In some embodiments of the invention, more than one error correction code is used for the data section, for example, with different parts of the data section using different codes. Optionally, the whole control section shares a single one of these codes with a data section. Alternatively, different parts of the control section share the codes of different data sections. Alternatively or additionally, the control section uses both error correction codes.

An aspect of some embodiments of the invention relates to using a two-tiered error detection and correction scheme for a control section. In an exemplary embodiment of the invention, the control section has an associated error detection code, for example capable of detecting one, two, three or more errors. If the detection code indicates that there is an error in the control section and the detection code cannot fix it, an error correction code shared by the control section and at least part of an associated data sector, is used to fix the control area. In an exemplary embodiment of the invention, using the error correction code includes at least reading (e.g., in order to understand the code) and, optionally, correcting at least part of the data sector as well. Alternatively, the error correction code is shared by a plurality of control sections.

In exemplary embodiments of the invention a tradeoff is realized between ease of updating an error correction code (e.g., how much data needs to be read to calculate the error correction code) and the storage size of the code. In some embodiments of the invention, the ease of updating a code goes down as a greater number of and more disparate functional components share the code. In an exemplary embodiment of the invention, it is expected that control information be typically accessed in conjunction with the data associated by the control information, so the added burden is not too large. However, other functional units may share codes. In some embodiments of the invention, the storage size of the code for a memory size is reduced as the number of different codes used is reduced. Thus, protecting a 512 byte section and a 16 byte section separately may require more code storage area than if a singe code is used for 528 bytes. In some embodiments of the invention, the difficulty of applying an error correction code is ignored. Alternatively it is not. For example, in some embodiments of the invention, the two tiered approach is used to reduce the frequency of using the error correction code to where errors are actually found.

In an exemplary embodiment of the invention, the control section error detection code has no correction ability. Alternatively, it has a limited correction ability. In either case, in an exemplary embodiment of the invention, a complete desired error correction ability is provided by the data sector code, optionally in conjunction with the control section code and not solely by the control section code.

In an exemplary embodiment of the invention, when a single control section is covered by two error correction codes, one of the codes may not be up to date. In this case, a record may be kept (e.g., a one bit flag or a counter) of which error correction code is more recent and that code used.

There is thus provided in accordance with an exemplary embodiment of the invention, a method of accessing control information of a non-volatile solid state memory storage, comprising:

reading said control information;

reading error correction code data shared by said control information and by other associated data;

analyzing said error correction code data to determine if said control information is erroneous; and

if erroneous, correcting said control information based on said error correction code data. Optionally, said analyzing and said correcting comprises a single integrated process. Alternatively or additionally, said memory is Flash memory in which only large memory units can be erased at a time. Alternatively or additionally, said control information is not accessible to user applications on a host computer which has access to said storage. Alternatively or additionally, said control information has a size of less than 10% of said other associated data. Alternatively or additionally, said control information is duplicated in said storage. Alternatively or additionally, said other data comprises a data sector associated with said control information.

There is also provided in accordance with an exemplary embodiment of the invention, a method of accessing control information of a solid state non-volatile memory storage, comprising:

reading said control information and error detection code data for said control information;

analyzing said error detection code data to determine if said control information is erroneous beyond an ability of said error detection code data to correct; and

if said control information is erroneous beyond said ability to correct:

reading a data section associated with said control information and having associated error correction code data for said data section and for said control information; and

correcting said control information using said error correction code data. Optionally, said data section comprises a data sector for which said control information serves as control tags.

In an exemplary embodiment of the invention, said error detecting code has no error correcting ability. Alternatively, said error detecting code has a limited error correcting ability, which does not provide a required reliability for said control information.

Optionally, said storage has an error rate of higher than 1:10⁶ per bit.

In an exemplary embodiment of the invention, said storage comprises flash memory.

Optionally, said error correction code data also corrects for errors in said error detection code data Alternatively, wherein said error detection code data detects errors in said error correction code data

In an exemplary embodiment of the invention, a total size of said error correction code is smaller than a combined size of an error correction code for said data and an error correction code for said control information, for a certain desired reliability.

In an exemplary embodiment of the invention, said method comprises correcting said data section using said error correction code data.

In an exemplary embodiment of the invention, said method comprises rewriting said control information to a different physical location in said storage in response to determination of an error in said control information.

There is also provided in accordance with an exemplary embodiment of the invention, a flash memory storage system, comprising:

a plurality of data sectors;

a plurality of control information sections, each associated with one or more data sectors and including an error detecting code for said control information; and

a plurality of error correction code data elements, each associated with at least one data sector and one control information section. Optionally, the system comprises a plurality of error detection code data elements associated each associated with at least one control information section.

### BRIEF DESCRIPTION OF THE FIGURES

Some non-limiting embodiments of the present invention will now be described in the following detailed description of exemplary embodiments of the invention and with reference to the attached drawings, in which same number designations are maintained throughout the figures for each element and in which:

FIG. 1 is a block diagram of a non-volatile memory system coupled to a computer, in accordance with an exemplary embodiment of the invention; and

FIG. 2 is a flowchart of a method of reading and correcting control information, in accordance with an exemplary embodiment of the invention.

### DETAILED DESCRIPTION OF EXEMPLARY EMBODIMENTS

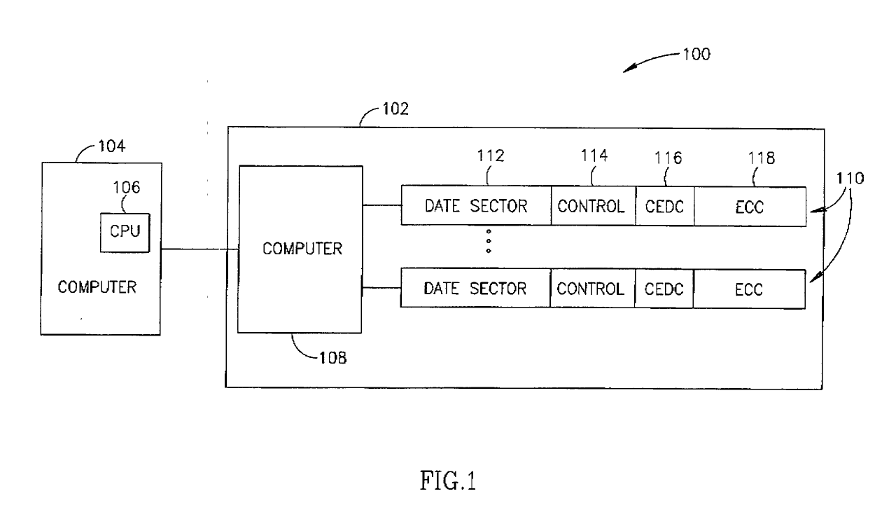

FIG. 1 is a block diagram 100 of a non-volatile memory system 102 coupled to a computer 104, in accordance with an exemplary embodiment of the invention. As shown, computer 104 includes a CPU 106 and memory system 102 includes a controller 108. As shown, memory system 102 also includes a plurality of memory areas 110, each of which includes a data sector 112, a control section 114 and other sections, as will be described below.

It should be appreciated that the present invention is intended to cover a wide range of memory configuration and the particular one illustrated should not be construed as limiting the invention to only that implementation. For example, the control section may not be contiguous with the data sector, the arrangement may be other than in sectors and/or various types of control circuitry may be provided

In an exemplary embodiment of the invention, control section 114 has associated therewith a control error detection code (CEDC) 116 which can be used to determine if the control section has errors. Optionally, data sector 112 has associated with it an error correction code (ECC) 118, which, in an exemplary embodiment of the invention, corrects errors in both data sector 112 and control section 114. Optionally, ECC 118 is also used to correct error correction code 116.

Substantially any type of error detection code may be used for code 116, including, for example, parity codes, checksums, Hamming, BCH and Reed-Solomon codes. It should be noted that some of these codes, such as some types of parity codes, do not allow any error correction. Substantially any type of error correction code may be used for code 118, for example Trellis codes, linear convolutional code, BCH and Reed-Solomon codes. A property of some types of codes is that they must be applied to the data as a whole, if they are to be meaningful, for example, requiring all the data to be read and/or be corrected as a whole. The reading and correction may be a single integrated step or it may be two steps, for example, after the data is read and analyzed, the existence of errors can be determined and then these errors corrected, of desire, using further processing.

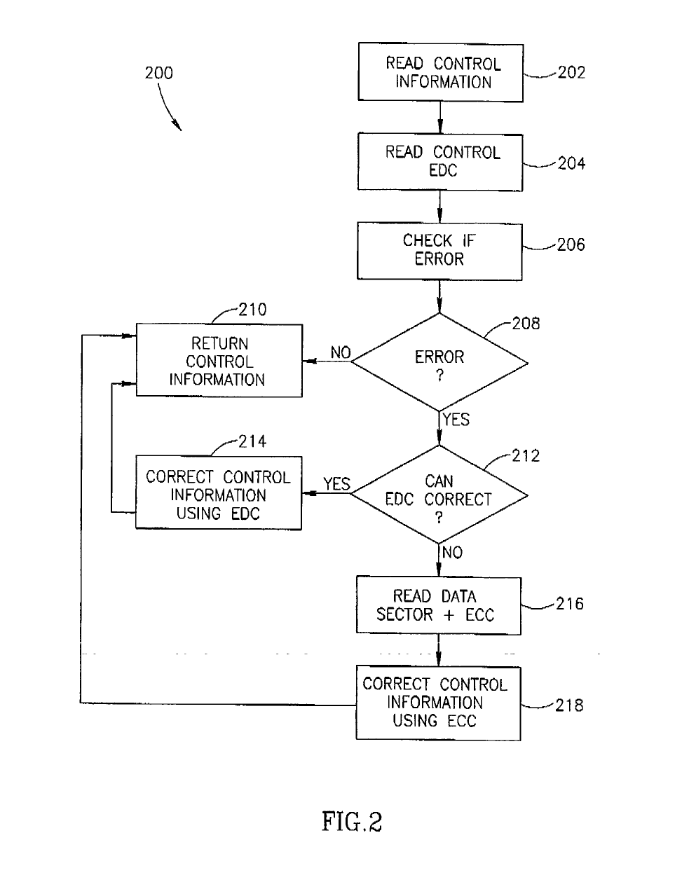

FIG. 2 is a flowchart 200 of a two tiered method of reading and correcting control information, in accordance with an exemplary embodiment of the invention. At 202 control section 114 is read. Its associated error detection code 116 is also read (204), to allow checking for errors (206). Substantially any type of error detection code may be used for this task. A low storage requirement, is typically, however, a desirable trait in such a code.

If no error was detected (208), the control information is returned and/or otherwise used (210).

If an error was detected, it may be that error detection code 116 has a high enough order of correction to correct it (212). If so, for example if code 116 has a one bit correction ability and there is only one bad bit, code 116 is used to correct the control information (214) and the control information is used (210). Alternatively or additionally, a duplicated control area is used to correct the error. For example, the current control area may be marked dirty, so only a pre-existing alternative control area is used. In an alternative embodiment of the invention, a new control area is created ad hoc, for example selected from an available pool (e.g., arranged as a list or linked list) and used to provide an alternative control area. A map or a search may be used to identify these control areas when an original control area is marked dirty. Thus, in some embodiments of the invention a data section does not need to be copied due to an error in a control section

Optionally, the control information is corrected in the memory only when rewritten after it is used and/or if a time passes without it being rewritten, instead of immediate correction. Alternatively or additionally, the correction of the control information is managed by a host computer, rather than by an onboard memory controller, for example.

In some embodiments and/or for some codes, reading out the data and detecting errors is applied as a single step. In others, there may be separate steps of analyzing the control information and of correcting the control information.

In some cases, the error detection code can only detect errors (e.g., one, two or three bits) and/or detect an error in more bits than its ability to correct. In this case, an associated data section 112 is read, along with its associated error correction code 118 (216). At 218, the control information is corrected by applying the error correction code to both the data and the control sections. While this may seem to be a wasteful operation, just to correct some control bits, in an exemplary embodiment of the invention, correction of errors is not required very often, so the additional overhead may be relatively small. In an alternative embodiment of the invention, the possible existence of errors in the data sector is ignored, and only errors in the control section are searched for and/or corrected. This may be done, for example, when only the control data is currently required and not the sector data. This is the case, for example, when the controlling software only needs to know if the sector is empty or used. If any errors are found in the data section, various procedures may be performed, for example, ignoring the error, rewriting the block and/or marking the block as bad.

When deciding what order to make codes 116 and 118, various considerations may be used. In one example, it is assumed that the error rate for control information and data sections is the same. This is not an essential feature of the invention, but it should be noted that different reliability levels may affect the calculation of the order of correction required. Thus, for a particular bit error rate, it is much more likely that the data section have a certain number of errors than that a control section have the same number of errors, since the data section is considerably larger than the control section. In an exemplary embodiment of the invention, if the bit error rate is better than 1:10⁷ and the desired reliability is better than 1:10⁸ bad sectors, a data section with 10,000 bits is set up with an error correction code 118 that can correct up to three bits. The control section, being smaller, e.g., 100 bits, needs only the correction of two bits. In accordance with an exemplary embodiment of the invention, the control error detection code has the ability to detect the above two bit errors, but not to correct them. Correction of two errors is provided by the data section error correction code. It should be noted that, in general, it is not necessarily required to increase the error correction order of code 118 beyond what would have been required for correcting only the data sector. For example, assuming the above bit error rate and required bad sector rate, it may be sufficient if code 118 can correct 3 bits, no matter if the errors are both in the data section and in the control section or just in the data section. In an exemplary embodiment of the invention, the error codes are configured to correct the same order of errors no matter how they are spread between the data and control sections, however, this is not required and other schemes may be used. The probability of having two errors in the control section and more than one error in the data section is less than 10⁻¹⁶, significantly better than the required bad sector rate. In other examples, however, it may be required to increase the correction order of code 118 to accommodate the additional task of correcting errors in the control section.

In an exemplary embodiment of the invention, EDC 116 is a Hamming code of one byte length, used to protect 7 bytes of control information and capable of correcting one error and detecting two. ECC 118 is a BCH code of 7 bytes length which corrects up to four errors in all 512 bytes of a data sector and 8 bytes of combined control information and EDC 116.

In an exemplary embodiment of the invention, the software and/or circuitry for writing data and/or control information to the memory are modified and/or written so that any writing updates error correction code 118, possibly requiring reading or providing from a different memory the data that is not being written (e.g., control information for writing data or vice versa). In an exemplary embodiment of the invention, the memory is part of a permanent or removable flash memory disk, for example having more than 1 or 16 MB. Optionally, the memory uses a dedicated driver or special software to emulate a block device to other hardware and/or software components. Such a special driver may be especially useful if the flash memory is arranged to have erase blocks that are considerably larger than a data sector, for example, 16 KB or 128 KB erase blocks for a 512 byte sector.

The above error detection and correction scheme may be applied to a variety of solid state storage technologies, for example, NVRAM, Flash memory (NOR and/or NAND), MRAM and/or FeRAM. In addition, the scheme may be applied to various arrangements of the memory. For example, the control section may be associated with a single or several data sectors. Alternatively or additionally, the control section may be duplicated, with each duplicate enjoying the benefit of an error correction code. Alternatively or additionally, an error correction code is shared by multiple control information sections and by pairs of data sections and control information.

In an exemplary embodiment of the invention, the above reliability increasing scheme is used in conjunction with lower quality memory. This may be useful for manufacturing a solid state disk emulator using lower reliability (but possibly faster, lower power and/or cheaper) components. Alternatively or additionally, reducing the reliability may be useful in providing less hardened devices or devices which are exposed to various environmental and/or handling extremes, for example when used as personal data exchange media in place of diskettes.

The error correction process and error detection process may be performed at a same location, for example, in controller 108. Alternatively, they may be separate, for example, one or the other being performed on controller 108 and the other on CPU 106 (e.g., as part of a driver).

Optionally, CPU 106 performs part or all of the error detection and correction. Optionally, the performance by CPU 106 is used to increase the reliability of an existing solid state memory device, possibly without changing the hardware and/or software of the memory device, with any required algorithms and setting up of control information and codes being provided, for example, by a dedicated driver on the host.

One potential advantage of performing calculation on CPU 106 is that this may reduce a required computational power of controller 108. Separating the error detection and error correction processes (in time and/or space) in this case, possibly reduces the bandwidth required for sending data back and forth between device 102 and computer 104, since error correction will be applied on computer 104 (requiring the transfer of the whole data sector) only if error detection finds an error, which is not often.

In an alternative embodiment of the invention in which two tiered detection and correction is not applied, no separate control section error detection code 116 is provided. Instead, error detection and correction relies on shared error correction code 118. Optionally, a separate, shared, error detection code is provided for the data and control information.

It should be note that the above numerical examples are for illustrative use only. Real devices may use these or other values. In addition, while the above calculations assume that the errors are unrelated, the method may be similarly be applied for other types of statistics of errors. The calculations may, of course, be different.

It will be appreciated that the above described methods may be varied in many ways, including, changing the order of steps and/or performing some steps in parallel. In addition, different apparatus arrangements may be used. For example, memory configurations and file systems may be used. It should also be appreciated that the above described description of methods and apparatus are to be interpreted as including apparatus constructed and/or programmed for carrying out the methods and methods of using the apparatus. It should be understood that features and/or steps described with respect to one embodiment may be used with other embodiments and that not all embodiments of the invention have all of the features and/or steps shown in a particular figure or described with respect to one of the embodiments. Variations of embodiments described will occur to persons of the art.

It is noted that some of the above described embodiments may describe a best mode contemplated by the inventors and therefore may include structure, acts or details of structures and acts that may not be essential to the invention and which are described as examples. Structure and acts described herein are replaceable by equivalents which perform the same function, even if the structure or acts are different, as known in the art. Therefore, the scope of the invention is limited only by the elements and limitations as used in the claims. When used in the following claims, the terms “comprise”, “include”, “have” and their conjugates mean “including but not limited to”.

1. A method of accessing control information of a non-volatile solid state memory storage, comprising:
reading said control information;
reading error correction code data shared by said control information and by other associated data;
analyzing said error correction code data to determine if said control information is erroneous; and
if erroneous, correcting said control information based on said error correction code data.

2. A method according to claim 1, wherein said analyzing and said correcting comprises a single integrated process.

3. A method according to claim 1, wherein said memory is Flash memory in which only large memory units can be erased at a time.

4. A method according to claim 1, wherein said control information is not accessible to user applications on a host computer which has access to said storage.

5. A method according to claim 1, wherein said control information has a size of less than 10% of said other associated data.

6. A method according to claim 1, wherein said control information is duplicated in said storage.

7. A method according to claim 1, wherein said other data comprises a data sector associated with said control information.

8. A method of accessing control information of a solid state non-volatile memory storage, comprising:
reading said control information and error detection code data for said control information;
analyzing said error detection code data to determine if said control information is erroneous beyond an ability of said error detection code data to correct; and
if said control information is erroneous beyond said ability to correct:
reading a data section associated with said control information and having associated error correction code data for said data section and for said control information; and
correcting said control information using said error correction code data.

9. A method according to claim 8, wherein said data section comprises a data sector for which said control information serves as control tags.

10. A method according to claim 8, wherein said error detecting code has no error correcting ability.

11. A method according to claim 8, wherein said error detecting code has a limited error correcting ability, which does not provide a required reliability for said control information.

12. A method according to claim 8, wherein said storage has an error rate of higher than 1:10⁶ per bit.

13. A method according to claim 8, wherein said storage comprises flash memory.

14. A method according to claim 8, wherein said error correction code data also corrects for errors in said error detection code data.

15. A method according to claim 8, wherein said error detection code data detects errors in said error correction code data.

16. A method according to claim 8, wherein a total size of said error correction code is smaller than a combined size of an error correction code for said data and an error correction code for said control information, for a certain desired reliability.

17. A method according to claim 8, comprising correcting said data section using said error correction code data.

18. A method according to claim 8, comprising rewriting said control information to a different physical location in said storage in response to determination of an error in said control information.

19. A flash memory storage system, comprising:
a plurality of data sectors;
a plurality of control information sections, each associated with one or more data sectors and including an error detecting code for said control information; and
a plurality of error correction code data elements, each associated with at least one data sector and one control information section.

20. A system according to claim 19, comprising a plurality of error detection code data elements associated each associated with at least one control information section.
